(19) United States
(12) Patent Application Publication
(10) Pub. No.: US 2026/0343924 A1
(43) Pub. Date: Oct. 29, 2026

(54) METHOD OF FORMING SEMICONDUCTOR STRUCTURE

(71) Applicant: Winbond Electronics Corp., Taichung City (TW)

(72) Inventor: Ting-Wei WU, Taichung City (TW)

(21) Appl. No.: 19/454,811

(22) Filed: Jan. 21, 2026

(30) Foreign Application Priority Data
Apr. 29, 2025 (TW) 114116035

(51) Int. Cl. H10D 30/01; H10D 30/68; H10D 64/01; H10D 64/66; H10D 84/01; H10D 84/83

(52) U.S. Cl. CPC H10D 30/0411; H10D 64/021; H10D 64/675; H10D 84/0147; H10D 30/68; H10D 84/83

(57) ABSTRACT

A method of forming a semiconductor structure is provided. The method of forming the semiconductor structure includes the following steps. A substrate is provided. A gate structure is formed on the substrate. A spacer layer is formed on the gate structure. A sacrificial layer is formed on the spacer layer. A dielectric plug is formed on the spacer layer. The sacrificial layer is etched back to expose the first portion of a sidewall of the spacer layer. A protective member is formed on the sacrificial layer. The sacrificial layer is removed. The spacer layer is removed to expose the substrate. The protective member is removed. A contact is formed on the substrate.

### CROSS REFERENCE TO RELATED APPLICATIONS

This Application claims priority of Taiwan Patent Application No. 114116035, filed on Apr. 29, 2025, the entirety of which is incorporated by reference herein.

### BACKGROUND OF THE INVENTION

### Field of the Invention

The present disclosure relates to a method of forming a semiconductor structure, and, in particular, it relates to an improved method of forming a semiconductor structure.

### Description of the Related Art

As semiconductor structures become increasingly scaled down, this miniaturization can exacerbate the problem of leakage current between adjacent components within the semiconductor structure. Although existing methods for forming semiconductor structures have gradually met their intended purposes, they still do not completely satisfy requirements in all respects. Therefore, several issues remain to be overcome in methods for forming a semiconductor structure.

### BRIEF SUMMARY OF THE INVENTION

A method of forming a semiconductor structure is provided. The method of forming a semiconductor structure includes the following steps. A substrate is provided. A gate structure is formed on the substrate. A spacer layer is formed on the gate structure. A sacrificial layer is formed on the spacer layer. A dielectric plug is formed on the spacer layer. The sacrificial layer is etched back to expose a first portion of a sidewall of the spacer layer. A protective member is formed on the sacrificial layer. The sacrificial layer is removed. The spacer layer is removed to expose the substrate. The protective member is removed. A contact is formed on the substrate.

The method of forming the semiconductor structure may be applied in a variety of electronic devices. In order to make the features and advantages of the present disclosure more comprehensible, various embodiments are specially cited hereinafter, collectively with the accompanying drawings, to be described in detail as follows.

### BRIEF DESCRIPTION OF THE DRAWINGS

FIGS. 1 to 10 are schematic cross-sectional views illustrating various stages of a method of forming a semiconductor structure according to an embodiment of the present disclosure.

### DETAILED DESCRIPTION OF THE INVENTION

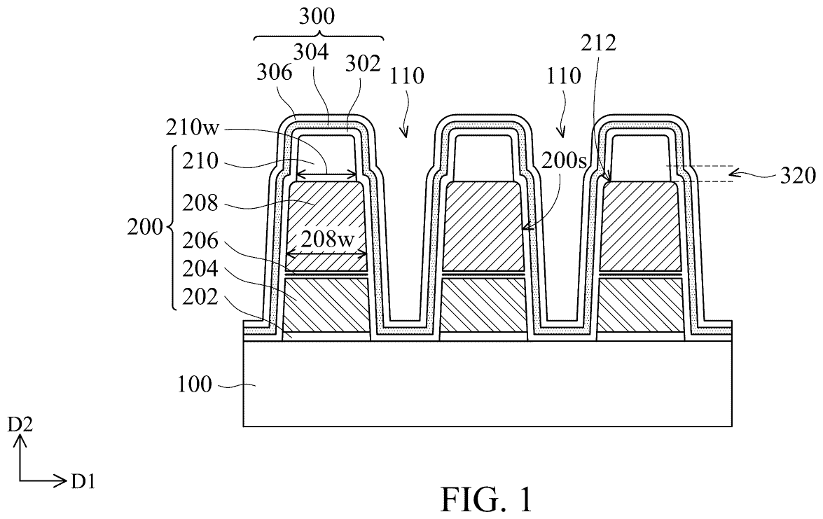

FIGS. 1 to 10 are schematic cross-sectional views illustrating various stages of a method of forming a semiconductor structure according to an embodiment of the present disclosure. Referring to FIG. 1, a substrate 100 is provided. The substrate 100 may include a silicon wafer, a bulk semiconductor, or a semiconductor-on-insulator (SOI) substrate. In an embodiment, the substrate 100 may be a multilayer substrate or a graded substrate. The substrate 100 may be an elemental semiconductor including silicon or germanium. In an embodiment, the substrate 100 may be a compound semiconductor including silicon carbide, gallium arsenide, gallium phosphide, indium phosphide, indium arsenide, indium antimonide, or the like, or a combination thereof, but the present disclosure is not limited thereto. In an embodiment, the substrate 100 may be an alloy semiconductor including SiGe, GaAsP, AlInAs, AlGaAs, GaInAs, GaInP, GaInAsP, or the like, or a combination thereof, but the present disclosure is not limited thereto. In an embodiment, the substrate 100 may be a doped or undoped semiconductor substrate.

As shown in FIG. 1, in an embodiment, gate structures 200 may be formed on the substrate 100. An opening 110 is defined between adjacent gate structures 200. The gate structure 200 may include a tunneling dielectric layer 202, a floating gate 204, an inter-gate dielectric layer 206, a control gate 208, and a mask layer 210. In an embodiment, the tunneling dielectric layer 202 may be disposed on the substrate 100, the floating gate 204 may be disposed on the tunneling dielectric layer 202, the inter-gate dielectric layer 206 may be disposed on the floating gate 204, the control gate 208 may be disposed on the intergate dielectric layer 206, and the mask layer 210 may be disposed on the control gate 208. In an embodiment, each stacked layer of the gate structure 200 may be formed by performing a deposition process such as a chemical vapor deposition (CVD) process, a physical vapor deposition (PVD) process, a sputtering process, an evaporation process, or the like, or a combination thereof; and performing a removal process such as an etching process, or the like, or a combination thereof.

As shown in FIG. 1, in an embodiment, the tunneling dielectric layer 202, the inter-gate dielectric layer 206, and the mask layer 210 may each independently include an oxide such as silicon oxide, a nitride such as silicon nitride, an oxynitride such as silicon oxynitride, or the like, or a combination thereof, but the present disclosure is not limited thereto. For example, the tunneling dielectric layer 202 may include an oxide such as silicon oxide. The inter-gate dielectric layer 206 may include an oxide-nitride-oxide (ONO) multilayer structure, such as a silicon oxide-silicon nitride-silicon oxide multilayer structure. The mask layer 210 may include an oxide such as silicon oxide. In an embodiment, the floating gate 204 and the control gate 208 may each independently include a doped or undoped conductive material. In an embodiment, the conductive material may include polysilicon; amorphous silicon; a metal such as tungsten, copper, silver, gold, or cobalt; a metal nitride such as tungsten nitride or titanium nitride; a conductive metal oxide; or the like; or a combination thereof, but the present disclosure is not limited thereto. For example, the floating gate 204 and the control gate 208 may include polysilicon.

As shown in FIG. 1, in an embodiment, the width 210w of the mask layer 210 may be smaller than the width of other components below the mask layer 210, such as the width 208w of the control gate 208. Therefore, the sidewall 200s of the gate structure 200 may have a turning point 212.

As shown in FIG. 1, in an embodiment, a spacer layer 300 may be conformally formed on the substrate 100. The spacer layer 300 covers the gate structure 200 and the bottom of the opening 110. In an embodiment, the material and formation method of the spacer layer 300 may be the same as or different from the material and formation method of the tunneling dielectric layer 202. In an embodiment, the spacer layer 302 may be formed on the gate structure 200 and the substrate 100, the spacer layer 304 may be formed on the spacer layer 302, and the spacer layer 306 may be formed on the spacer layer 304. For example, the spacer layer 302 may include silicon oxide, the spacer layer 304 may include silicon nitride, and the spacer layer 306 may include silicon oxide.

As shown in FIG. 1, in an embodiment, because the spacer layer 300 is conformally formed on the gate structure 200 having the turning point 212, the spacer layer 300 may include a turning portion 320 corresponding to the turning point 212. For example, the top surface of the control gate 208 in the spacer layer 300 may be substantially coplanar with the bottom surface of the turning portion 320. Furthermore, because the spacer layer 300 has a thickness, the turning degree of the turning portion 320 is enhanced. The turning portion 320 of the spacer layer 300 may also be referred to as a kink.

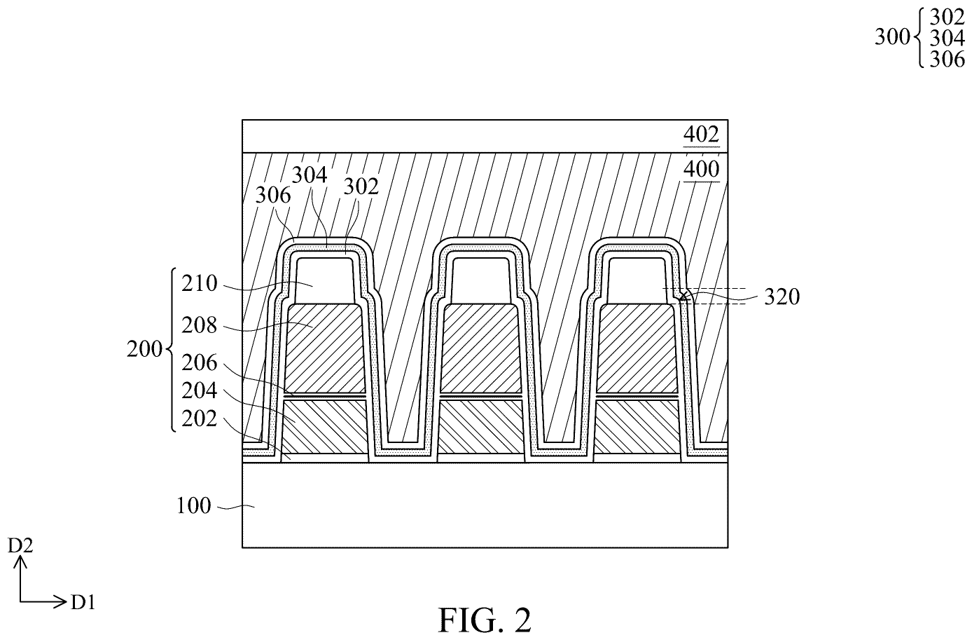

Next, as shown in FIG. 2, a sacrificial layer 400 is blanket deposited on the spacer layer 300, and a mask layer 402 is formed on the sacrificial layer 400. In an embodiment, the sacrificial layer 400 may include polysilicon. In another embodiment, the mask layer 402 may include silicon nitride, silicon oxide, amorphous carbon, or the like, or a combination thereof, but the present disclosure is not limited thereto.

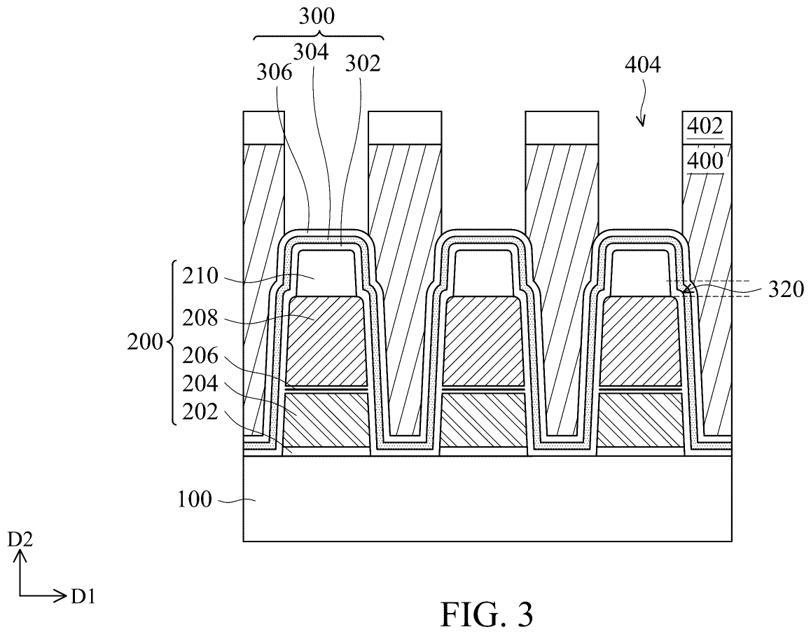

Next, as shown in FIG. 3, the mask layer 402 is patterned, and the sacrificial layer 400 is removed using the patterned mask layer 402 as an etching mask to form an opening 404. As shown in FIG. 3, the opening 404 exposes the top surface of the spacer layer 300.

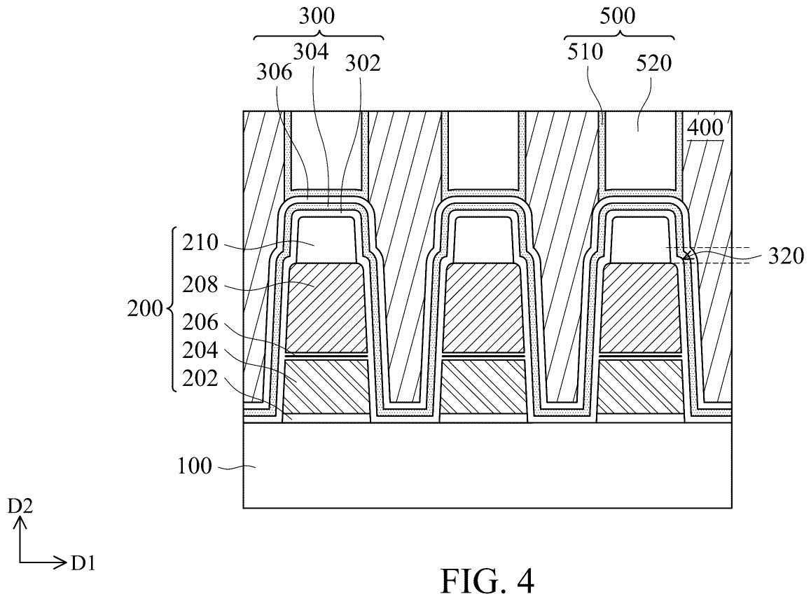

Next, as shown in FIG. 4, a dielectric plug 500 is formed in the opening 404 and on the spacer layer 300. In an embodiment, the dielectric plug 500 may include a liner 510 and a dielectric layer 520 disposed on the liner 510. In an embodiment, the liner 510 may be conformally formed in the opening 404, and the dielectric layer 520 may be formed on the liner 510. Next, a planarization process may be performed to make the top surfaces of the sacrificial layer 400, the liner 510, and the dielectric layer 520 coplanar. In an embodiment, the material and formation method of the dielectric plug 500 may be the same as or different from the material and formation method of the tunneling dielectric layer 202. For example, the liner 510 may include silicon nitride, and the dielectric layer 520 may include silicon oxide. In some embodiments, the liner 510 may be omitted.

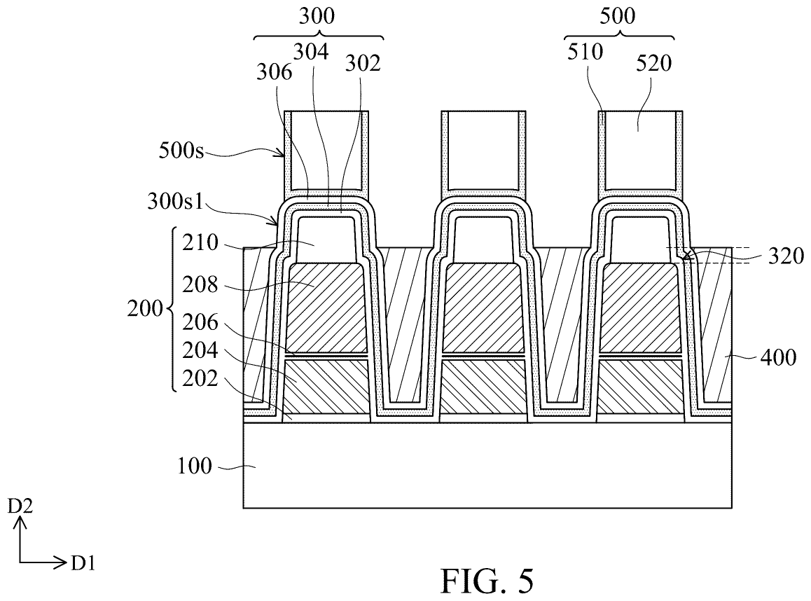

Next, as shown in FIG. 5, the sacrificial layer 400 may be etched back to expose the sidewalls 500s of the dielectric plug 500 and a portion of the sidewalls 300s1 of the spacer layer 300. In an embodiment, the sacrificial layer 400 may be etched back by reactive ion etching or wet etching to remove a portion of the sacrificial layer 400 while retaining the remaining portion of the sacrificial layer 400. In an embodiment, the remaining portion of the sacrificial layer 400 covers the turning portion 320 of the spacer layer 300.

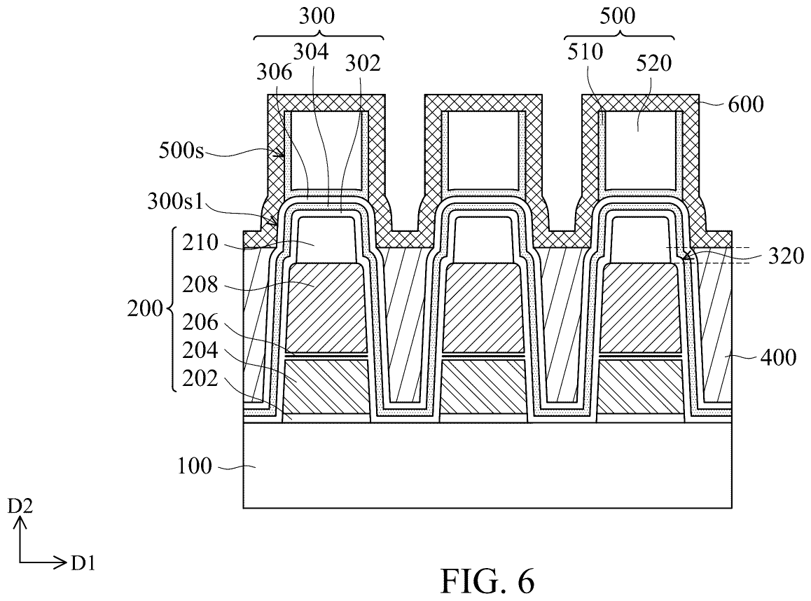

Next, as shown in FIG. 6, a protective layer 600 is conformally formed to cover the top surface and sidewalls 500s of the dielectric plug 500, the exposed portion of the sidewalls 300s1 of the spacer layer 300, and the top surface of the sacrificial layer 400. In an embodiment, the protective layer 600 may include a carbon-rich material. For example, the carbon-rich material may include diamond-like carbon, spin-on carbon, a high-selectivity transparent film, or the like, or a combination thereof, but the present disclosure is not limited thereto.

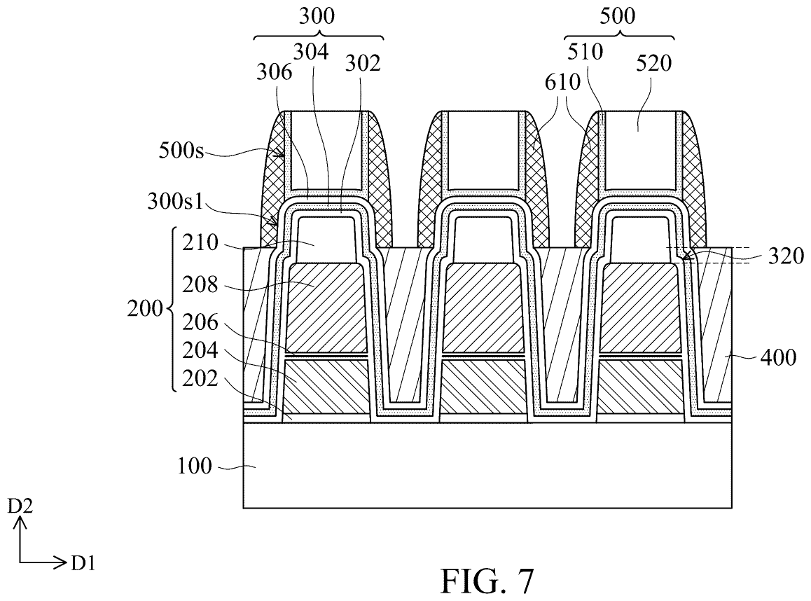

Next, as shown in FIG. 7, a portion of the protective layer 600 is removed to form a protective member 610 on the sacrificial layer 400. In an embodiment, the horizontal portion of the protective layer 600 may be removed by reactive ion etching, while retaining the vertical portion of the protective layer 600. The protective member 610 exposes the top surface of the sacrificial layer 400. The protective member 610 covers the sidewalls 500s of the dielectric plug 500 and a portion of the sidewalls 300s1 of the spacer layer 300. As shown in FIG. 7, in the direction D2, the protective member 610 covers the turning portion 320 of the spacer layer 300, thereby protecting the turning portion 320 of the spacer layer 300 from etching and defects during subsequent etching processes.

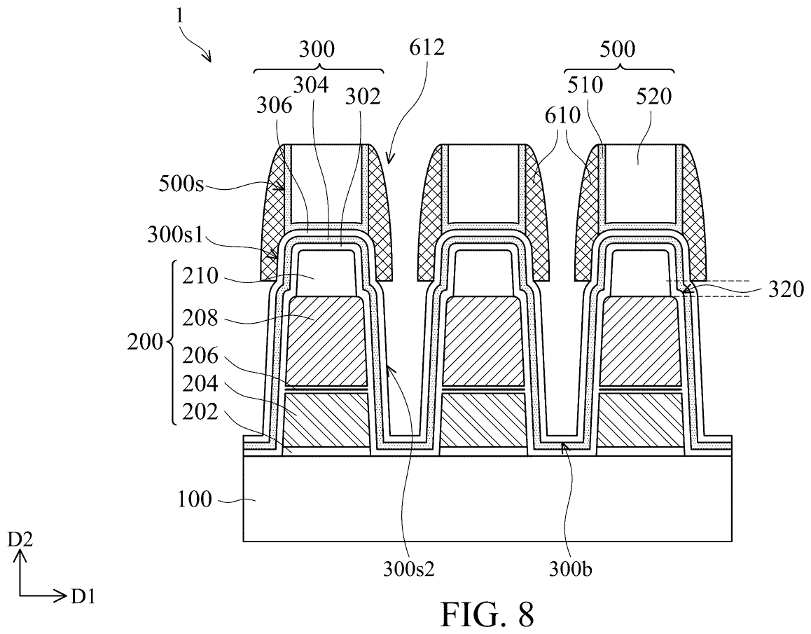

Next, as shown in FIG. 8, after forming the protective member 610, the sacrificial layer 400 may be removed to form an opening 612. The opening 612 exposes a portion of the sidewall 300s2 and the bottom 300b of the spacer layer 300. In an embodiment, the sacrificial layer 400 may be removed by a wet etching process. Compared to the portion of the sidewall 300s1 of the spacer layer 300, the portion of the sidewall 300s2 of the spacer layer 300 may be closer to the substrate 100. The opening 612 exposes the bottom of the protective member 610.

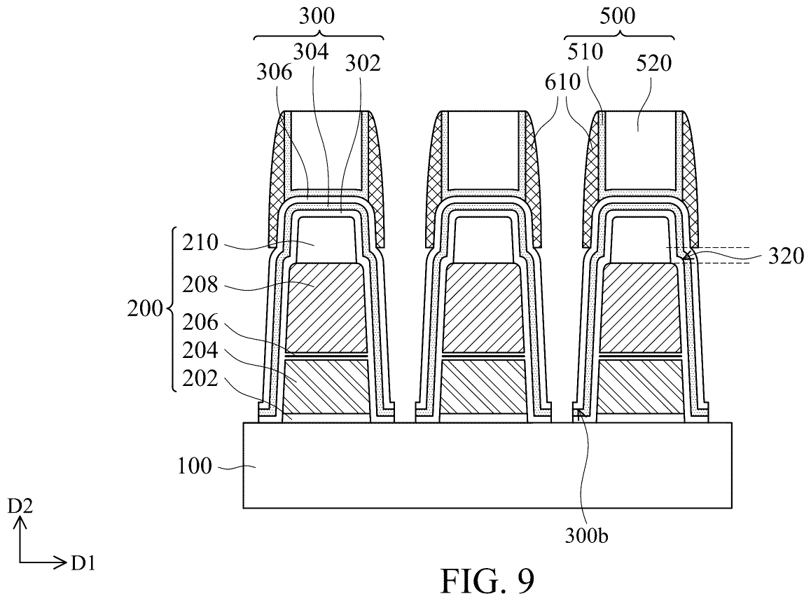

Next, as shown in FIG. 9, a portion of the bottom 300b of the spacer layer 300 may be removed to expose the top surface of the substrate 100. In an embodiment, the portion of the bottom 300b of the spacer layer 300 may be removed by reactive ion etching. During the reactive ion etching process, because the reactive ions are directional (e.g., bombarding in a direction opposite to the direction D2), the protective member 610 may effectively prevent the plasma ions used in the reactive ion etching process from damaging the turning portion 320 of the spacer layer 300, so that the spacer layer 300 fully covers the gate structure 200. This may improve the electrical performance, reliability, and/or process margin of the semiconductor structure.

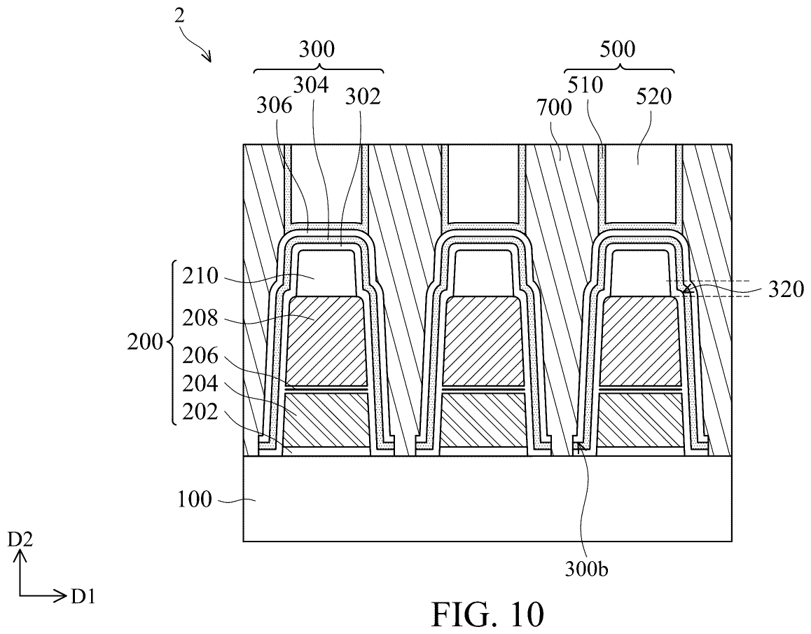

Next, as shown in FIG. 10, after the top surface of the substrate 100 is exposed, the protective member 610 may be removed. Then, a contact 700 may be formed on the exposed substrate 100 and electrically connected to the substrate 100 to form the semiconductor structure 2. In an embodiment, the material and formation method of the contact 700 may be the same as or different from the material and formation method of the floating gate 204. For example, the contact 700 may include tungsten.

Accordingly, the present disclosure may prevent the etching process from damaging the spacer layer on the gate structure by forming a protective member, thereby avoiding the problem of leakage current between adjacent gate structures or adjacent contacts. For example, the problem of plasma ions damaging the spacer layer in the ion etching process may be effectively avoided by adjusting the placement position of the protective member. Among them, when the placement position of the spacer is too low, it will be difficult to open through the spacer layer. On the other hand, when the placement position of the spacer is too high, the plasma ions may still reflect and bombard the spacer layer. Furthermore, the present disclosure may maintain the spacer layer with a uniform thickness without substantially damaging the spacer layer. For example, based on the thickness of the spacer layer before opening through the spacer layer as a reference (100%), at least 95%, 97%, 99%, or more of the thickness of the spacer layer may be retained. Thereby, the electrical performance, reliability and/or process margin of the method of forming the semiconductor structure may be improved.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
providing a substrate;
forming a gate structure on the substrate;
forming a spacer layer on the gate structure;
forming a sacrificial layer on the spacer layer;
forming a dielectric plug on the spacer layer;
etching back the sacrificial layer to expose a first portion of a sidewall of the spacer layer;
forming a protective member on the sacrificial layer;
removing the sacrificial layer;
removing the spacer layer to expose the substrate;
removing the protective member; and
forming a contact on the substrate.

2. The method as claimed in claim 1, wherein the spacer layer comprises a turning portion, and the etched-back sacrificial layer covers the turning portion.

3. The method as claimed in claim 1, wherein the sacrificial layer is etched back to expose a sidewall of the dielectric plug.

4. The method as claimed in claim 1, wherein forming the protective member on the sacrificial layer further comprises:
forming a protective layer on the etched-back sacrificial layer; and
removing a horizontal portion of the protective layer to form the protective member on the sacrificial layer.

5. The method as claimed in claim 4, wherein the protective member exposes a top surface of the sacrificial layer.

6. The method as claimed in claim 1, wherein the protective member covers the first portion of the sidewall of the spacer layer.

7. The method as claimed in claim 1, wherein the protective member covers a sidewall of the dielectric plug.

8. The method as claimed in claim 1, wherein after forming the protective member on the sacrificial layer, the sacrificial layer is removed to form an opening.

9. The method as claimed in claim 8, wherein the opening exposes a second portion of the sidewall of the spacer layer, and the second portion of the sidewall of the spacer layer is closer to the substrate than the first portion of the sidewall.

10. The method as claimed in claim 8, wherein the opening exposes a bottom of the spacer layer.

11. The method as claimed in claim 10, wherein the bottom of the spacer layer is removed to expose the substrate.

12. The method as claimed in claim 8, wherein the opening exposes a bottom of the protective member.

13. The method as claimed in claim 1, wherein the gate structure comprises a tunneling dielectric layer, a floating gate, an inter-gate dielectric layer, a control gate, and a mask layer stacked sequentially.

14. The method as claimed in claim 13, wherein a width of the mask layer is smaller than a width of the control gate.

15. The method as claimed in claim 13, wherein the spacer layer comprises a turning portion, and a top surface of the control gate in the spacer layer is substantially coplanar with a bottom surface of the turning portion.

16. The method as claimed in claim 1, wherein the spacer layer comprises a first spacer layer, a second spacer layer, and a third spacer layer stacked sequentially, and a material of the second spacer layer is different from a material of the first spacer layer and a material of the third spacer layer.

17. The method as claimed in claim 16, wherein the material of the first spacer layer and the material of the third spacer layer are silicon oxide, and the material of the second spacer layer is silicon nitride.

18. The method as claimed in claim 1, wherein the spacer layer comprises a turning portion, the sacrificial layer is etched back, and the remaining portion of the sacrificial layer covers the turning portion of the spacer layer.

19. The method as claimed in claim 1, wherein the protective member comprises a carbon-rich material.

20. The method as claimed in claim 1, wherein the spacer layer comprises a turning portion, and the protective member covers the turning portion of the spacer layer.
